(19) United States
(12) Patent Application Publication
(10) Pub. No.: US 2012/0199932 A1
(43) Pub. Date: Aug. 9, 2012

(54) LOW NOISE, STABLE AVALANCHE PHOTODIODE

(75) Inventor: John E. Bowers, Santa Barbara, CA (US)

(73) Assignee: THE REGENTS OF THE UNIVERSITY OF CALIFORNIA, Oakland, CA (US)

(21) Appl. No.: 13/501,572

(22) PCT Filed: Oct. 7, 2010
(86) PCT No.: PCT/US10/51848

§ 371 Date: Apr. 12, 2012

Related U.S. Application Data
(60) Provisional application No. 61/250,792, filed on Oct. 12, 2009.

(51) Int. Cl. H01L 31/107

(52) U.S. Cl. 257/438; 257/E31.063

(57) ABSTRACT

Quantum avalanche photodiodes are disclosed. An avalanche photodiode in accordance with one or more embodiments of the present invention comprises an absorption region having a first dopant type, a collection region, having a second dopant type, and a multiplication region, coupled between the absorption region and the collection region, wherein a distance of the multiplication region between the absorption region and the collection region is a plurality of avalanche lengths.

### STATEMENT REGARDING FEDERALLY SPONSORED RESEARCH OR DEVELOPMENT

This invention was made with Government support under Agreement No. HR0011-06-3-0009 awarded by DARPA. The Government has certain rights in this invention.

### BACKGROUND OF THE INVENTION

1. Field of the Invention

The present invention relates generally to semiconductor devices, and, more specifically, to low noise, stable avalanche photodiodes.

2. Description of the Related Art

Avalanche photodiodes (APDs) are photodetectors which provide a built-in first stage of gain through avalanche multiplication. By applying a high reverse bias voltage, typically 100-200 V in silicon (Si), APDs show an internal current gain effect of approximately 100 due to the avalanche effect, also known as impact ionization.

However, many silicon APDs use alternative doping and/or beveling techniques compared to traditional APDs that use a larger applied voltage, e.g., >1000 volts, to be applied before breakdown is reached, which provides a greater operating gain value, e.g., >1000. In general, the higher the reverse voltage the higher the gain. Typically, the APD multiplication factor M is proportional to the multiplication coefficient for electrons (or holes), known as α. This coefficient has a strong dependence on the applied electric field strength, temperature, and doping profile. Since APD gain varies strongly with the applied reverse bias and temperature, it is necessary to control the reverse voltage in order to keep a stable gain. Avalanche photodiodes therefore are more sensitive in terms of noise and stability compared to other semiconductor photodiodes.

It can be seen, then, that there is a need in the art for stable APDs. It can also be seen that there is a need in the art for APDs that provide gain at lower reverse bias voltages.

### SUMMARY OF THE INVENTION

To minimize the limitations in the prior art, and to minimize other limitations that will become apparent upon reading and understanding the present specification, the present invention provides for quantum avalanche photodiodes. An avalanche photodiode in accordance with one or more embodiments of the present invention comprises an absorption region having a first dopant type, a collection region, having a second dopant type, and a multiplication region, coupled between the absorption region and the collection region, wherein a distance of the multiplication region between the absorption region and the collection region is a plurality of avalanche lengths.

Such an avalanche photodiode further optionally comprises a gain of the avalanche photodiode being quantized based on a number of avalanche lengths in the multiplication region, a reverse bias applied to the avalanche photodiode being less than 100 volts, the distance of the multiplication region being approximately 100 nanometers, a reverse bias point of the avalanche photodiode increasing voltage sensitivity of the avalanche photodiode, the reverse bias point of the avalanche photodiode also increasing noise output of the avalanche photodiode, the reverse bias point of the avalanche photodiode also increasing temperature sensitivity of the avalanche photodiode, the multiplication region being silicon, and a gain of the avalanche photodiode substantially doubling with every additional avalanche length included in the multiplication region.

An avalanche photodiode having a quantized gain in accordance with one or more embodiments of the present invention comprises an absorption region, a collection region, and a multiplication region, coupled between the absorption region and the collection region, wherein the quantized gain is proportional to a number of avalanche lengths in the multiplication region.

Such an avalanche photodiode further optionally comprises a reverse bias applied to the avalanche photodiode being less than 100 volts, a distance of the multiplication region between the absorption region and the collection region being approximately 100 nanometers, a reverse bias point of the avalanche photodiode increasing voltage sensitivity of the avalanche photodiode, the reverse bias point of the avalanche photodiode also increasing noise output of the avalanche photodiode, the reverse bias point of the avalanche photodiode also increasing temperature sensitivity of the avalanche photodiode, and the multiplication region being silicon.

Other features and advantages are inherent in the system disclosed or will become apparent to those skilled in the art from the following detailed description and its accompanying drawings.

### BRIEF DESCRIPTION OF THE DRAWINGS

Referring now to the drawings in which like reference numbers represent corresponding parts throughout:

FIG. 1 illustrates an avalanche photodiode;

FIG. 2 illustrates an intrinsic (multiplication) layer in an avalanche photodiode in accordance with the present invention;

FIG. 3 illustrates a gain versus voltage curve in an avalanche photodiode in accordance with the present invention;

FIG. 4 illustrates a voltage sensitivity versus voltage curve in an avalanche photodiode in accordance with the present invention;

FIG. 5 illustrates a noise versus voltage curve in an avalanche photodiode in accordance with the present invention; and

FIG. 6 illustrates a temperature sensitivity versus voltage curve in an avalanche photodiode in accordance with the present invention.

### DETAILED DESCRIPTION OF THE PREFERRED EMBODIMENTS

In the following description, reference is made to the accompanying drawings which form a part hereof, and which is shown, by way of illustration, several embodiments of the present invention. It is understood that other embodiments may be utilized and structural changes may be made without departing from the scope of the present invention.

### Overview

APDs are usually designed, fabricated and analyzed assuming continuous generation of charge. However, the ionization events that occur within an APD are quantized in nature. In an APD, a single carrier causes an ionization event and creates an electron-hole pair. The carrier must first be accelerated (i.e., after a “dead region”) and gained at least a bandgap of energy before the ionization event can occur. There are a few examples where the fact that ionization events occur only after a dead region is utilized, e.g., InP and InGaAlAs APD gain regions, where a superlattice structure is used to change the effective ratio of electron and hole ionization rates and get improved performance.

The present invention, however, utilizes an inherent difference in ionization rates, e.g, in silicon, where the rates are very different for electrons and holes. In such a case, with a thin gain region, avalanche conditions will only occur for one type of charge carrier. In the case of silicon, the hole ionization rate is 100 times less than the electron ionization rate, and so the hole ionization can be essentially neglected in analysis and design of a silicon APD.

Second, the present invention uses much thinner gain regions than traditional APDs, and employs these thinner gain regions at very high electric field strengths. This is different from the typical region of operation for silicon where the gain regions are thick and the voltages are high, often 1000 V for silicon. An example of the present invention recently constructed by the inventor comprises a silicon APD with a 25 V reverse bias and a 0.5 micron thick avalanche region.

The present invention can also be extended into an even smaller regions of operation and even thinner avalanche regions, e.g., to a reverse bias voltage of less than 10 Volts, and less than or equal to 5 Volts, and an approximately 100 nm thick avalanche region. Such voltages are available in digital circuitry, and thus, APDs can now be integrated with such circuitry using the present invention. Further, the avalanche region can also be thinner or thicker than 100 nm if desired, or the reverse bias voltage reduced, based on the maximum gain desired in any given design.

### Avalanche Photodiode Diagram

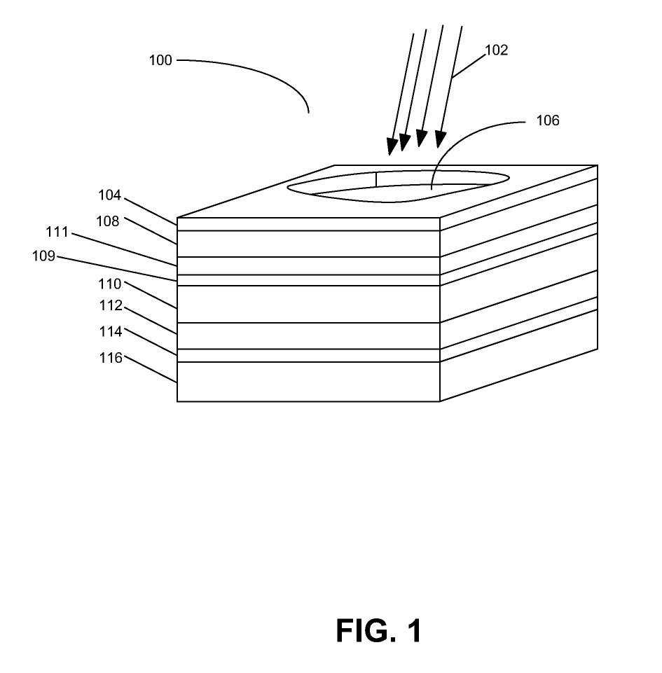

FIG. 1 illustrates an avalanche photodiode.

Avalanche photodiode (APD) 100 is shown, with photons 102 at a wavelength of interest striking APD 100. Top metal contact 104 can be transparent at a given wavelength, or have an opening 106 to expose the p-type layer 108, also known as the absorption region 108 to photons 102. As photons 102 strike p-type layer 108, additional electron-hole pairs are created in avalanche region 109, typically within the depletion region created by the interface between p-type layer 108 and avalanche region 109. There can also be a charge layer 111 between the intrinsic region 110 and the p-type layer 108, if desired, to adjust the electric field level within APD 100. The width of the depletion region can be, and typically is, increased by the presence of n-type layer 112, also known as the collection region 112, in close proximity to the p-type layer 108.

N-contact layer 114 and metal contact layer 116 are coupled to the opposite side of n-type layer 112, to provide electrical contacts to APD 100. Although shown as n-type layer 112 and p-type layer 108, the dopants may be reversed in polarity for a given APD 100 design without departing from the scope of the present invention.

### Quantum/Digital APD Effects

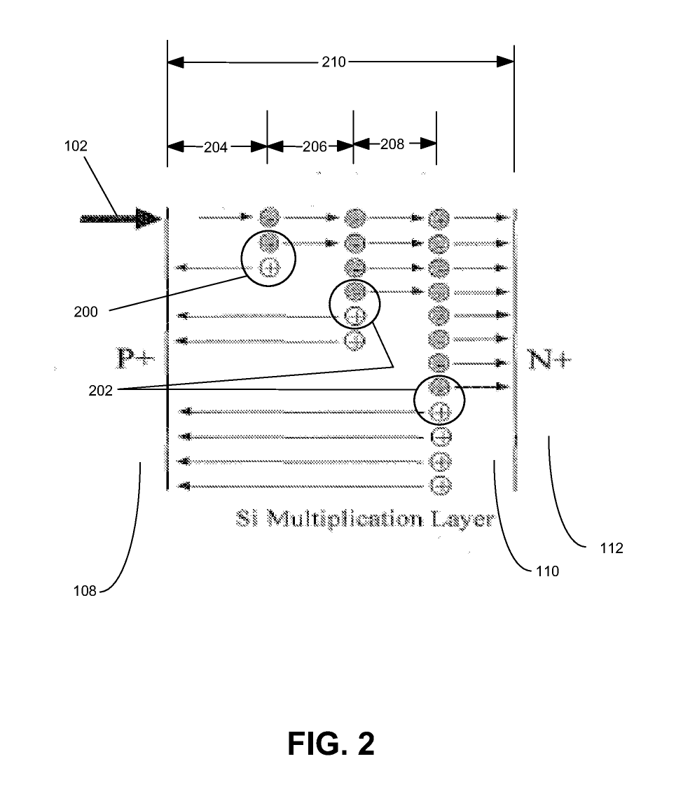

FIG. 2 illustrates an intrinsic (multiplication) layer in an avalanche photodiode in accordance with the present invention.

The APD of the present invention displays four separate types of effects, i.e., quantized gain, periodic increases in the voltage sensitivity, spikes in the noise output, and increase in the sensitivity of the APD gain versus temperature.

Within the present invention, the maximum gain of the APD is likely limited, probably to values of less than 150, and typically values of 8 to 128. Further, the gain values are typically factors of 2, e.g., 2, 4, 8, 16, 32, etc., and these factors are based on the finite numbers of avalanche lengths present in a given APD design.

As shown in FIG. 2, as photogenerated electrons are injected into the high field region and create electron-hole pairs 200 and/or 202 in avalanche region 109, also known as the “multiplication” region 109. The creation of electron-hole pairs 200 and/or 202 are ionization events that occur at specific locations within avalanche multiplication region 109. In the present invention, advantage is made of the multiplication region 109, where rather than creating electron-hole pairs 200, 202 at every depth, creates electron-hole pairs 200, 202 at specific depths of the multiplication region 109, e.g., at depths 204, 206, 208, and that these depths or lengths are at specific locations, within the multiplication region 110. Further, the entire length 210 of the multiplication region 110 also needs to be designed such that the electron-hole pairs created by initial photon 102 absorption and by avalanche multiplication are not reabsorbed in the multiplication region 110 after creation.

The present invention employs a design that uses a finite number of avalanche lengths 204-208 in the APD 100, as shown in FIG. 2, it is seen that an APD that uses three avalanche lengths 204, 206, and 208 will likely produce a gain of 8, and an APD that uses seven avalanche lengths 204, 206, 208, etc., will likely produce a gain of 128, such that the number of avalanche lengths acts as the exponent “x” in a 2^{x} equation for the gain of that specific APD 100. Further, the distance between length 208 and the other lengths 202-206 may be unrelated to gain of APD 100, as once electron-hole pairs are generated at lengths 204, 206, and 208, the desire to retrieve all of the electron-hole pairs 200 without recombination or additional noise may require that the difference between length 210 and length 208 be smaller or larger than the difference between successive lengths 204-208.

### Quantized Gain

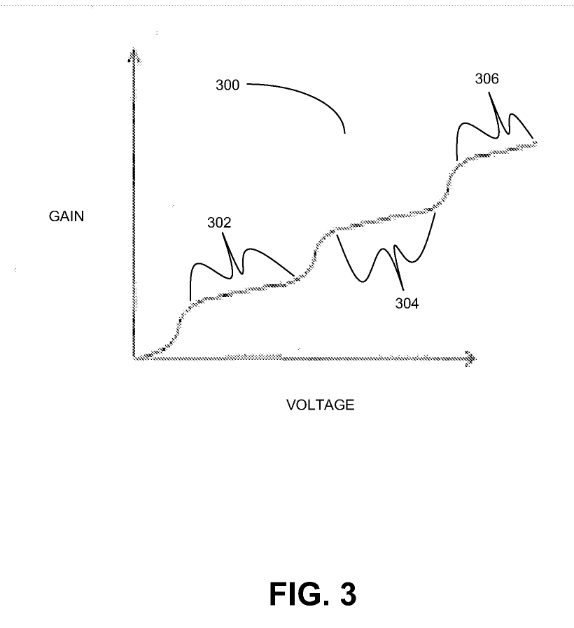

FIG. 3 illustrates a gain versus voltage curve in an avalanche photodiode in accordance with the present invention.

The present invention operates the APD 100 at a high density electric field so the avalanche lengths 204-208 are short, and such that other processes such as electron or phonon scattering are not significant within multiplication region 110. As such, the distribution of ionization lengths is quite narrow and the ionization events all occur in approximately the same location within multiplication layer 110. The first effect of this narrow distribution is evident in curve 300, i.e., the gain versus voltage curve, where sections 302, 304, 306 of curve 300 are relatively flat. Every time there is another avalanche length 204-208, the gain doubles. As such, the present invention provides, within a specific multiplication layer 110 length 210, regions of operation for a range of voltage where the gain is relatively insensitive to a change in voltage, which provides a more stable APD 100.

### Periodic Increases in Voltage Sensitivity

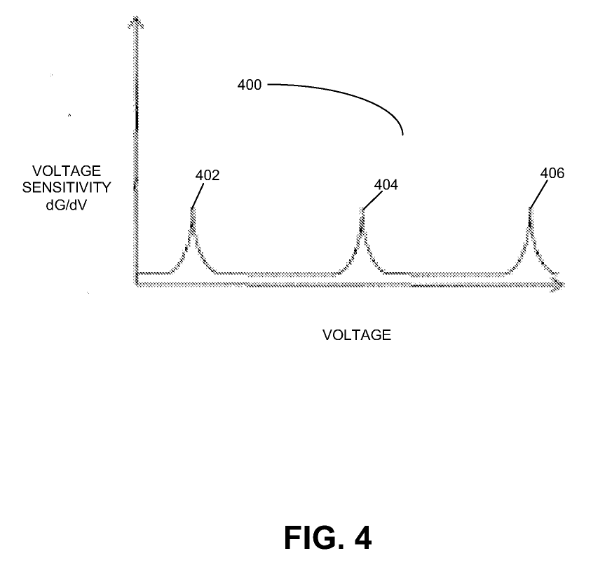

FIG. 4 illustrates a voltage sensitivity versus voltage curve in an avalanche photodiode in accordance with the present invention.

The second effect of the design of the multiplication layer 110 in accordance with the present invention shows that curve 400, namely, the voltage sensitivity versus voltage curve, shows periodic spikes 402, 404, and 406 in the voltage sensitivity of APD 100 at specific voltages.

### Spikes in Noise Output

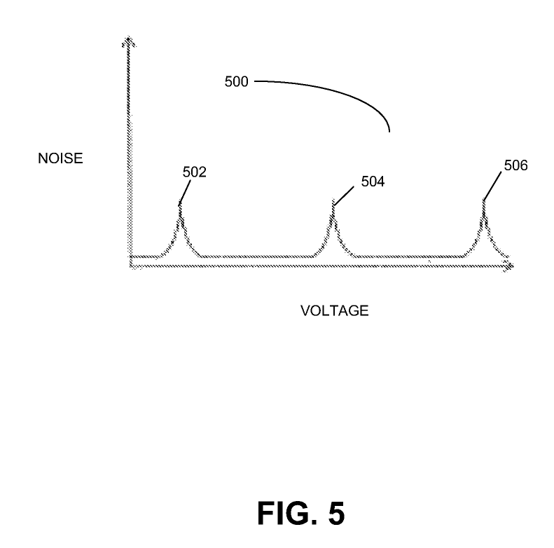

FIG. 5 illustrates a noise versus voltage curve in an avalanche photodiode in accordance with the present invention.

When the last ionization event occurs at the boundary of the multiplication layer 110 region, some electrons will ionize and some will not. This lack of unity between ionized electrons and generated electrons will generate additional noise at the output of the APD 100 (via the contacts 102 and 114). This effect of the design of the multiplication layer 110 in accordance with the present invention shows that curve 500, namely, the noise versus voltage curve, shows periodic spikes 502, 504, and 506 in the noise generated by APD 100.

At other voltages (where N+½ ionization lengths fit in the gain region (where N is an integer)), none of the electrons have experienced another ionization event (e.g. N+1 ionization events from injection to collection). The spikes 502-506 occur at given voltages, which are the same given voltages where spikes 402-406 occurred with respect to FIG. 4.

### Spikes in Temperature Sensitivity

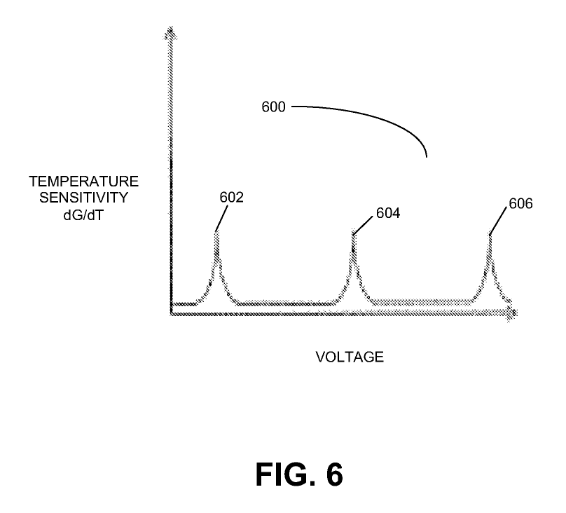

FIG. 6 illustrates a temperature sensitivity versus voltage curve in an avalanche photodiode in accordance with the present invention.

This effect of the design of the multiplication layer 110 in accordance with the present invention shows that curve 600, namely, the temperature sensitivity versus voltage curve, shows periodic spikes 602, 604, and 606 in the temperature sensitivity of the APD 100.

This fourth effect is an increase in the sensitivity of the gain to temperature. Again, when there are N+½ ionization events (where N is an integer), there will be a very small temperature sensitivity. When there are N ionization lengths, there will be a large temperature sensitivity because a small change in temperature take the devices towards a gain of 2N or a gain of 2N+1.

The spikes 602-606 occur at given voltages, which are the same given voltages where spikes 402-406 occurred with respect to FIG. 4 and spikes 502-506 occurred with respect to FIG. 5. As such, operation of the APD 100 of the present invention at voltages other than the bias points corresponding to spikes 402-406, 502-506, and 602-606 will result in a relatively constant gain, relatively low noise, and relatively temperature and voltage independent APD 100 output.

Since all of the reverse bias voltages align with respect to noise, voltage sensitivity, and temperature sensitivity, the present invention applies these advantages to properly design the quantized multiplication layer 110 of the APD. When there are N+½ ionization lengths, the gain is 2^{N}, and there is minimal gain sensitivity, minimal temperature sensitivity and minimal noise output. Where there is an integral number of ionization lengths in the APD, the APD is noisy and quite sensitive to temperature and voltage. In comparing a normal APD to a quantum APD, the good regions of the quantum APD should be better than a normal APD (lower noise, lower voltage and temperature sensitivities). The bad regions of the quantum APD should be worse than a normal APD, i.e. more noisy output, and greater voltage and temperature sensitivity.

### CONCLUSION

In summary, embodiments of the invention provide for quantum avalanche photodiodes. An avalanche photodiode in accordance with one or more embodiments of the present invention comprises an absorption region having a first dopant type, a collection region, having a second dopant type, and a multiplication region, coupled between the absorption region and the collection region, wherein a distance of the multiplication region between the absorption region and the collection region is a plurality of avalanche lengths.

Such an avalanche photodiode further optionally comprises a gain of the avalanche photodiode being quantized based on a number of avalanche lengths in the multiplication region, a reverse bias applied to the avalanche photodiode being less than 100 volts, the distance of the multiplication region being approximately 100 nanometers, a reverse bias point of the avalanche photodiode increasing voltage sensitivity of the avalanche photodiode, the reverse bias point of the avalanche photodiode also increasing noise output of the avalanche photodiode, the reverse bias point of the avalanche photodiode also increasing temperature sensitivity of the avalanche photodiode, the multiplication region being silicon, and a gain of the avalanche photodiode substantially doubling with every additional avalanche length included in the multiplication region.

An avalanche photodiode having a quantized gain in accordance with one or more embodiments of the present invention comprises an absorption region, a collection region, and a multiplication region, coupled between the absorption region and the collection region, wherein the quantized gain is proportional to a number of avalanche lengths in the multiplication region.

Such an avalanche photodiode further optionally comprises a reverse bias applied to the avalanche photodiode being less than 100 volts, a distance of the multiplication region between the absorption region and the collection region being approximately 100 nanometers, a reverse bias point of the avalanche photodiode increasing voltage sensitivity of the avalanche photodiode, the reverse bias point of the avalanche photodiode also increasing noise output of the avalanche photodiode, the reverse bias point of the avalanche photodiode also increasing temperature sensitivity of the avalanche photodiode, and the multiplication region being silicon.

The foregoing description of the preferred embodiment of the invention has been presented for the purposes of illustration and description. It is not intended to be exhaustive or to limit the invention to the precise form disclosed. Many modifications and variations are possible in light of the above teaching. It is intended that the scope of the invention be limited not by this detailed description, but by the claims attached hereto and the full breadth of equivalents to the claims.

What is claimed is:

1. An avalanche photodiode, comprising:
an absorption region having a first dopant type;
a collection region, having a second dopant type; and
a multiplication region, coupled between the absorption region and the collection region, wherein a distance of the multiplication region between the absorption region and the collection region is a plurality of avalanche lengths.

2. The avalanche photodiode of claim 1, wherein a gain of the avalanche photodiode is quantized based on a number of avalanche lengths in the multiplication region.

3. The avalanche photodiode of claim 1, wherein a reverse bias applied to the avalanche photodiode is less than 20 volts.

4. The avalanche photodiode of claim 1, wherein the distance of the multiplication region is less than 200 nanometers.

5. The avalanche photodiode of claim 1, wherein a reverse bias point of the avalanche photodiode increases voltage sensitivity of the avalanche photodiode.

6. The avalanche photodiode of claim 5, wherein the reverse bias point of the avalanche photodiode also decreases noise output of the avalanche photodiode.

7. The avalanche photodiode of claim 6, wherein the reverse bias point of the avalanche photodiode also decreases temperature sensitivity of the avalanche photodiode.

8. The avalanche photodiode of claim 1, wherein the multiplication region is silicon.

9. The avalanche photodiode of claim 1, wherein a gain of the avalanche photodiode substantially doubles with every additional avalanche length included in the multiplication region.

10. An avalanche photodiode having a quantized gain, comprising:
an absorption region;
a collection region; and
a multiplication region, coupled between the absorption region and the collection region, wherein the quantized gain is proportional to a number of avalanche lengths in the multiplication region.

11. The avalanche photodiode of claim 10, wherein a reverse bias applied to the avalanche photodiode is less than 20 volts.

12. The avalanche photodiode of claim 10, wherein a distance of the multiplication region between the absorption region and the collection region is less than 200 nanometers.

13. The avalanche photodiode of claim 10, wherein a reverse bias point of the avalanche photodiode decreases voltage sensitivity of the avalanche photodiode.

14. The avalanche photodiode of claim 13, wherein the reverse bias point of the avalanche photodiode also decreases noise output of the avalanche photodiode.

15. The avalanche photodiode of claim 14, wherein the reverse bias point of the avalanche photodiode also decreases temperature sensitivity of the avalanche photodiode.

16. The avalanche photodiode of claim 10, wherein the multiplication region is silicon.
